(19) United States
(12) Patent Application Publication
(10) Pub. No.: US 2020/0225259 A1
(43) Pub. Date: Jul. 16, 2020

(54) OPTICAL FIBER PROBE FOR MEASURING LOCAL TWO-PHASE FLOW PARAMETERS, METHOD OF MANUFACTURING THE OPTICAL FIBER, AND METHOD OF MEASURING TWO-PHASE FLOW PARAMETERS

(71) Applicant: Pusan National University Industry-University Cooperation Foundation, Busan (KR)

(72) Inventors: Byong-Jo YUN, Busan (KR); Taeho KIM, Busan (KR); Byeonggeon BAE, Busan (KR); Taehwan AHN, Busan (KR); Jaejun JEONG, Busan (KR); Kyungdoo KIM, Incheon (KR)

(73) Assignee: Pusan National University Industry-University Cooperation Foundation, Busan (KR)

(21) Appl. No.: 16/526,362

(22) Filed: Jul. 30, 2019

(30) Foreign Application Priority Data
Jan. 10, 2019 (KR) 10-2019-0003329

(51) Int. Cl. G01P 5/00; G01R 1/073

(52) U.S. Cl. CPC G01P 5/001; G01R 1/07307

(57) ABSTRACT

Disclosed is an optical fiber probe for measuring parameters of a local two-phase flow, which is fixed to a probe holder of a two-phase flow measuring device and is installed in a flow path of a two-phase flow of a liquid phase fluid and a gas phase fluid. The optical fiber probe includes: a first tapered portion which is formed in a conical shape in which a diameter is gradually decreased at a certain ratio in an axial direction thereof to a point spaced a certain distance from a point thereof fixed to a probe holder, toward a leading end of the optical fiber probe; and a second tapered portion which is formed in a conical shape in which a diameter is gradually decreased at a greater ratio than that of the first tapered portion in an axial direction thereof from an end of the first tapered portion.

### CROSS-REFERENCE TO RELATED APPLICATION

This application claims priority to and the benefit of Korean Patent Application No. 10-2019-0003329 filed on Jan. 10, 2019, which is hereby incorporate by reference in its entirety.

### BACKGROUND

The present invention relates to an optic fiber probe for measuring parameters of a fluid flow, and more specifically, to a stretched conical single optical fiber probe (SC-SOFP) for measuring a local two-phase flow factor in a two-phase flow in which a droplet and a bubble are present, a method of manufacturing the optical fiber probe, and a method of measuring parameters of a fluid using the optical fiber probe.

A two-phase flow is a flow generated when two fluids having different phases and different characteristics such as water-steam, water-air, droplet and bubble-air, and droplet and bubble-steam are mixed. The two-phase flow mainly appears in industrial fields such as nuclear power, shipbuilding, marine, biomass, and petrochemical fields. In particular, in order to increase the safety and efficiency of a nuclear power plant in the nuclear power field, an accurate flow analysis of an accident situation is required, and accurate measurement of two-phase flow factors is required to develop a flow model for the accurate flow analysis. Examples of the major two-phase flow factors include droplet and bubble fractions, interface area density (IAC), and an interface velocity. Various measurement methods have been developed by previous researchers in order to measure the factors.

Examples of methods of measuring parameters of a local two-phase flow include a conductance sensor method, an impedance sensor method, and an optical fiber probe method. Among the methods, the optical fiber probe method is sensitive to a phase change and thus has a feature of accurately discriminating phases.

In the optical fiber method, an optical fiber probe uses a difference between intensities of light beams that are reflected according to a refractive index of an exposed medium after laser light supplied to an optical fiber reaches a probe portion along the optical fiber. The intensity of the light is converted into an electrical signal. By using a signal obtained from the optical fiber probe, it is possible to measure droplet and bubble fractions, an interface velocity, and droplet and bubble sizes, and IAC at a local point.

In a general optical fiber probe method, an interface velocity is measured by arranging two probes in a line at a certain interval, and then measuring a distance between the two probes and a difference between times taken for phases to pass through the probes.

However, since a micro-sized droplet and bubble may not pass through the two probes at the same time, it is not easy to measure an interface velocity through a double sensor tip. To solve such a problem, a method of measuring an interface velocity using a single optical fiber probe has been proposed. The method uses the fact that the change rate of a signal, which is generated when phases such as a droplet and a bubble pass through an optical fiber probe, is proportional to an interface velocity.

Meanwhile, a leading end of the conventional optical fiber probe is manufactured into a conical shape using a chemical etching method (see FIG. 2A) or is manufactured into a wedge-shape inclined at a certain angle (for example, 35°) with respect to a probe axis by polishing the leading end, thereby measuring necessary factors such as an interface velocity.

However, in the case of the leading end of the optical fiber probe formed in the conical shape, when a droplet or a bubble is detected at a low droplet velocity (see a graph of FIG. 3A), a change in signal is noticeable. When a droplet or a bubble is detected at a high velocity of 20 m/sec or more (see graph of FIG. 3B), signal distortions such as a change in base height and overshooting of droplet and bubble signals, which are caused by a wetting phenomenon of the optical fiber probe, are generated. In FIGS. 3A and 3B, the leftmost graphs show electrical signals detected when an conical optical fiber probe is used, and middle graphs show electrical signals detected when a wedge-shaped optical fiber probe of which a surface is polished at an angle of 35° is used. It may be confirmed that a change in base height or overshooting of a signal is generated due to a wetting phenomenon of a probe tip at a high droplet velocity (Ud) of 25 m/s

### Prior Art Documents

### Patent Documents

Korean Registered Patent No. 10-0352799 (registered on Sep. 2, 2002)

Korean Registered Patent No. 10-0545728 (registered on Jan. 17, 2006)

(Korean Patent Publication No. 10-2008-0012607 (published on Feb. 12, 2008)

### SUMMARY

The present invention is directed to providing an optical fiber probe capable of improving signal sensitivity and accurately measuring an interface velocity by preventing a wetting phenomenon from being generated when the interface velocity of a high velocity flow is measured in a two-phase flow in which a liquid phase fluid and a gas phase fluid (for example, a droplet and a bubble) are present, and a method of manufacturing the same.

In addition, the present invention is directed to providing a method of accurately measuring parameters such as a velocity and the like of a liquid phase fluid or a gas phase fluid flowing at a high velocity using a single optical fiber probe.

According to an embodiment of the present invention, an optical fiber probe for measuring parameters of a local two-phase flow includes a first tapered portion which is formed in a conical shape in which a diameter is gradually decreased at a certain ratio in an axial direction thereof to a point spaced a certain distance from a point thereof fixed to a probe holder of a two-phase flow measuring device, toward a leading end of the optical fiber probe; and a second tapered portion which is formed in a conical shape in which a diameter is gradually decreased at a greater ratio than that of the first tapered portion in an axial direction thereof from an end of the first tapered portion.

An angle formed between an outer surface of the second tapered portion and a central axis thereof may be 13.5°.

A length of the first tapered portion may be greater than a length of the second tapered portion.

The first tapered portion and the second tapered portion may be optical fibers made of a quartz material, and an outer surface of an optical fiber of the optical fiber probe excluding the first tapered portion and the second tapered portion may be coated with a polymer or plated with a conductive metal according to a use temperature environment.

According to an embodiment of the present invention, a method of manufacturing the optical fiber probe for measuring the parameters of the local two-phase flow of any one of claims 1 to 4 includes (S1) stretching one end of an optical fiber in an axial direction thereof to form a first tapered portion; and (S2) immersing and etching an end of the first tapered portion in an etching solution to form a second tapered portion.

The etching solution may be a hydrofluoric acid solution.

A method of measuring parameters of a liquid phase fluid or a gas phase fluid of a local two-phase flow using the optical fiber probe for measuring the parameters of the local two-phase flow includes (S11) acquiring a first derivative signal obtained by first-differentiating a raw signal detected by the optical fiber probe; (S12) acquiring a second derivative signal by differentiating the first derivative signal; and (S13) listing minimum and maximum peak values of the second derivative signal and minimum peak values of the first derivative signal in chronological order and determining a liquid phase fluid or a gas phase fluid.

In operation S13, a case, in which the minimum and maximum peak values detected through the second derivative signal and the minimum peak values detected through the first derivative signal are listed in chronological order to sequentially detect the minimum peak value of the second derivative signal, the minimum peak value of the first derivative signal, and the maximum peak value of the second derivative signal, may be determined that a signal is a droplet signal.

According to the present invention, since a sensing portion of an optical fiber probe is formed in a two-stage conical shape having a first tapered portion and a second tapered portion, a wetting phenomenon is not generated even when a phase flows at a high velocity. Thus, signal distortion phenomena such as a change in a base height and overshooting caused by a wetting phenomenon is not generated, and a change in signal is noticeable. Therefore, it is possible to accurately measure parameters of a specific phase (droplet or bubble) of a two-phase flow.

### BRIEF DESCRIPTION OF THE DRAWINGS

FIG. 1 is a view illustrating a two-phase flow measuring device to which an optical fiber probe (10) according to an embodiment of the present invention is applied. FIGS. 2A, 2B, and 2C show cross-sectional views illustrating conventional optical fiber probes including conical and wedge-shaped leading ends and an optical fiber probe including a two-stage conical leading end according to the present invention.

FIGS. 3A and 3B are graphs showing electrical signals according to a droplet velocity (Ud) and a droplet size (Dd) which are measured by the conventional optical fiber probes and the optical fiber probe according to the present invention.

FIG. 4 is a view illustrating an etching process for forming a second tapered portion of the optical fiber probe according to the embodiment of the present invention.

FIGS. 5A, 5B, and 5C show graphs showing an electrical signal measured by the optical fiber probe according to the present invention and a first differential signal and a second differential signal of the electrical signal.

FIG. 6 shows graphs showing a change rate (g_{rd}) of a signal, an average time (ΔT_{wet}) taken for a phase to pass through an optical fiber probe, and a phase fraction (α_{d}) at a phase interface which are measured by the optical fiber probe according to the present invention.

FIG. 7 is view illustrating a structural example of an artificial intelligence learning method using a tangent-sigmoid transfer function based on Bayesian normalization.

### DETAILED DESCRIPTION

Embodiments described herein and configurations illustrated in the drawings are merely exemplary examples of the present invention, and various modified examples that may substitute for the embodiments and the drawings of the present specification may exist at the time of filing the present application.

Hereinafter, an optical fiber probe for measuring parameters of a local two-phase flow, a method of manufacturing the optical fiber probe, and a method of measuring a fluid velocity using the probe will be described with reference to the accompanying drawings through embodiments to be described below. Like reference numerals indicate like elements throughout the drawings.

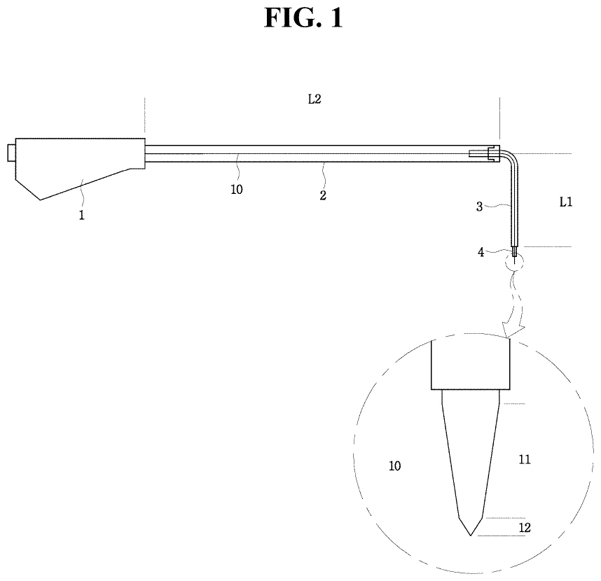

FIG. 1 is a view illustrating a two-phase flow measuring device, to which an optical fiber probe 10 according to an embodiment of the present invention is applied. The two-phase flow measuring device includes a probe head 1, a first guide tube 2 installed to extend in one direction from the probe head 1, a second guide tube 3 installed at a leading end of the first guide tube 2 to be bent in an approximate ¬ shape, a probe holder 4 installed at a leading end of the second guide tube 3 to fix the optical fiber probe 10, and the optical fiber probe 10 installed to sequentially pass through the probe head 1, the first guide tube 2, the second guide tube 3, and the probe holder 4 and having one end exposed to the outside of the probe holder 4.

When the measuring device is introduced into a flow path of a two-phase flow to perform a measuring operation, the probe head 1 is a portion which is held and supported by a person's hand or fixed to another fixing structure. The probe head 1 is manufactured so as to connect the optical fiber probe 10 to a laser oscillating unit and a receiving unit without damage to the optical fiber probe 10.

The first guide tube 2 may be formed in the form of a tube, may be a support which guides the optical fiber probe 10 into the flow path and supports the optical fiber probe 10, and may be made of a metal material such as stainless steel (SUS).

The second guide tube 3 has a diameter smaller than that of the first guide tube 2 and is bent in the approximate ¬ shape such that the optical fiber probe 10 is disposed in a flow direction. A connection portion between the first guide tube 2 and the second guide tube 3 is fixed and sealed with epoxy or silver solder.

The probe holder 4 is connected to a leading end of the second guide tube 3 and fixedly supports an end of the optical fiber probe 10 exposed to the outside. The probe holder 4 has a hole which has a size corresponding to a diameter of the optical fiber probe 10 and through which the optical fiber probe 10 passes. The optical fiber probe 10 is fixed to the probe holder 4 by epoxy or silver solder. The optical fiber probe 10 may have a structure in which a coating material 10c is applied on an outer surface of an optical fiber made of a quartz material. The optical fiber includes a core 10a and cladding 10b surrounding an outer surface of the core 10a.

A portion of the optical fiber probe 10 excluding a first tapered portion 11 and a second tapered portion 12 exposed to the outside of the probe holder 4 has a structure coated with the coating material 10c. A material of the coating material 10c varies according to a use temperature environment. In a case in which the coating material 10c is used at room temperature, the coating material 10c made of a polymer material is used. In this case, the optical fiber probe 10 is fixed to the probe holder 4 using a resin such as epoxy. The coating material 10c formed as a plated layer made of a conductive metal such as copper or gold is used at a high temperature. In this case, the optical fiber probe 10 may be fixed to the probe holder 4 using silver solder.

Thee optical fiber probe 10 is installed in a flow path of a two-phase flow of a liquid phase fluid and a gas phase fluid to perform a function of a sensor which measures factors such as an interface velocity, IAC, and a bubble fraction of the liquid phase fluid (for example, a droplet) or the gas phase fluid (for example, a bubble, air, or steam).

As shown in FIG. 2C, the optical fiber probe 10 includes the first tapered portion 11 which is formed in a conical shape in which a diameter is gradually decreased at a certain ratio in an axial direction thereof to a point spaced a certain distance from a point thereof fixed to the probe holder 4, toward a leading end of the optical probe holder, and the second tapered portion 12 which is formed in a conical shape of which a diameter is gradually decreased at a greater ratio than that of the first tapered portion 11 in an axial direction thereof from an end of the first tapered portion 11. The first tapered portion 11 and the second tapered portion 12 are optical fibers made of a quartz material.

An optical fiber portion of the optical fiber probe 10 excluding the first tapered portion 11 and the second tapered portion 12 has a diameter of about 125 μm (see FIGS. 2A-2C). The first tapered portion 11 and the second tapered portion 12 are formed in the conical shape in which a diameter is gradually decreased toward the leading end of the optical fiber probe 10.

Since the first tapered portion 11 and the second tapered portion 12 have the same central axis but diameter decrease ratios, i.e., slopes thereof are different, an inflection point is formed at a boundary point between the first tapered portion 11 and the second tapered portion 12.

The first tapered portion 11 is formed by stretching the optical fiber probe 10 in the axial direction and is formed to be longer than the second tapered portion 12. An angle formed between the central axis and an outer surface of the first tapered portion 11 is smaller than an angle formed between the central axis and an outer surface of the second tapered portion 12. An angle formed between the central axis and the outer surface of the second tapered portion 12 may be less than or equal to 13.5°.

The second tapered portion 12 is formed into a conical shape through an etching process and constitutes the leading end of the optical fiber probe 10.

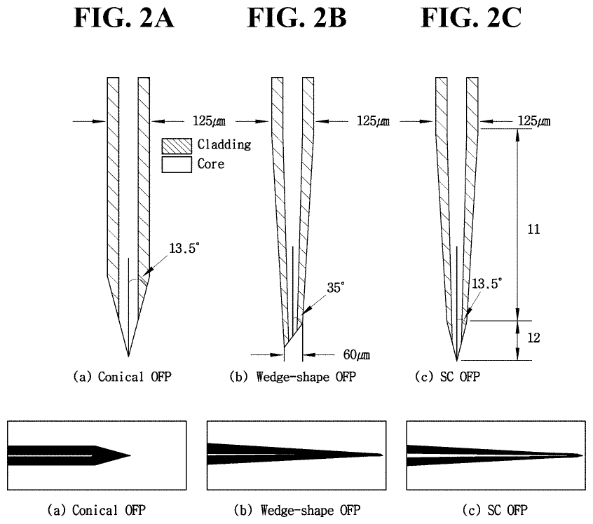

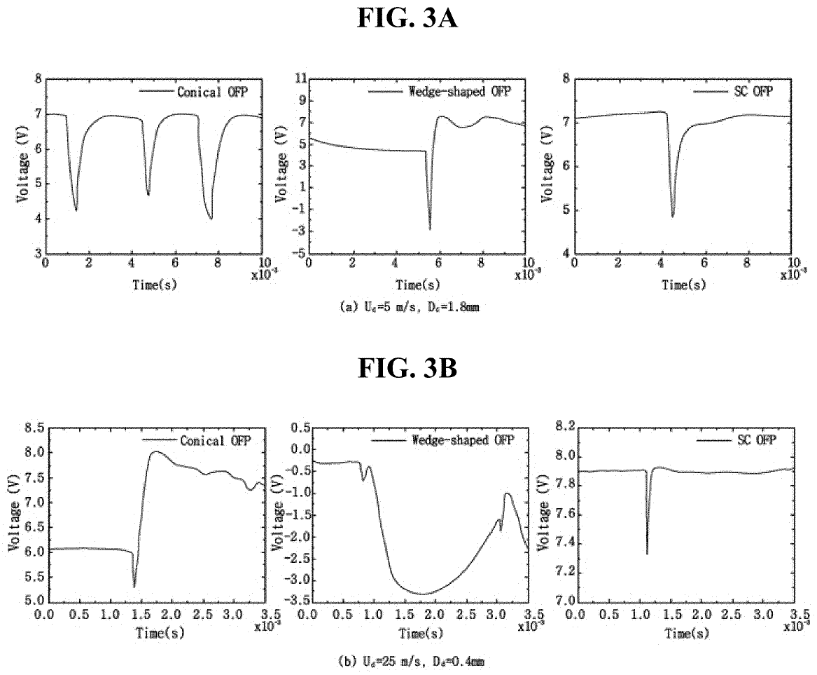

As confirmed from the rightmost graphs of FIGS. 3A and 3B, in the optical fiber probe 10 having a two-stage conical shape having the first tapered portion 11 and the second tapered portion 12, a change in signal is noticeable at a high droplet velocity as well as a low droplet velocity, and signal distortions such as a change in base height and overshooting caused by a wetting phenomenon are not generated. Therefore, it is possible to accurately measure parameters of a specific phase (such as a droplet or a bubble) in a two-phase flow.

The optical fiber probe 10 may be manufactured as follows.

First, the first tapered portion 11 is formed by stretching one end of an optical fiber in an axial direction thereof. A stretching process of the optical fiber may be performed using a micro-laser puller.

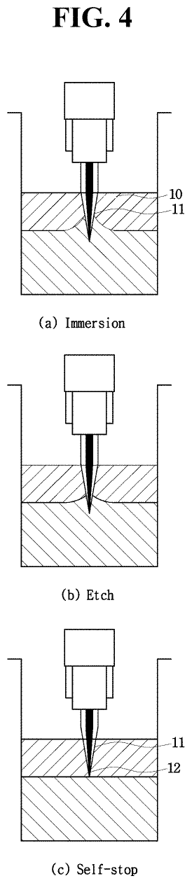

Then, as shown in FIG. 4, the second conical tapered portion 12 is formed by performing an etching process of immersing an end of the first tapered portion 11 in an etching solution for a certain time. A hydrofluoric acid solution may be used as the etching solution, and an etching time may be about 10 minutes.

Next, a method will be described which discriminates a liquid phase fluid (for example, a droplet) and a gas phase fluid (for example, a bubble) of a two-phase flow and measures a velocity among parameters of the liquid phase fluid or the gas phase fluid using the optical fiber probe 10 of the present invention.

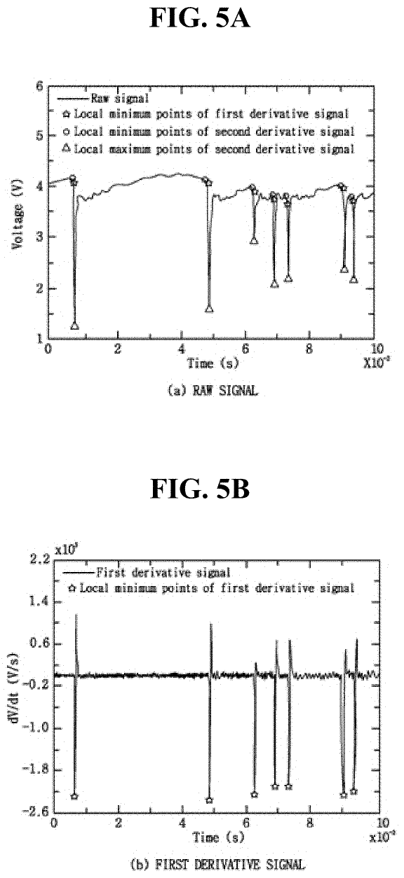

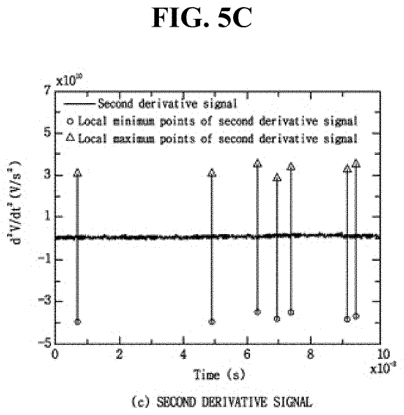

In order to derive parameters of a local droplet and bubble in an electrical signal obtained from the optical fiber probe 10, it is necessary to accurately discriminate a liquid phase and a gas phase. When base heights of signals of the liquid phase and the gas phase are constant, the two phases may be discriminated based on a constant height of a curve of an output signal. However, a height of a base signal corresponding to a gas phase of a raw signal of FIG. 5A is changed after a phase such as a droplet or bubble passes. The present invention proposes a method of detecting an interface of a droplet or bubble based on a first derivative and a second derivative of an output signal and measuring parameters such as a velocity and density of the droplet or bubble through the detected interface.

A signal of the optical fiber probe 10 is abruptly changed when of the optical fiber probe 10 passes through the interface of the droplet or bubble. FIGS. 5A, 5B, and 5C are graphs showing a raw signal, a first derivative signal, and a second derivative signal of a typical optical fiber probe obtained in a bubble-droplet flow. The first derivative signal (see FIG. 5B) has one minimum value within a range of a signal when one phase passes. Minimum and maximum values of the second derivative signal (see FIG. 5C) are obtained at points where the optical fiber probe touches front and rear interfaces of a phase when the optical fiber probe passes through the phase. Although it is possible to detect an interface of a phase using only the second derivative signal, there may be an error in an identification of the interface of the phase due to peaks from noise in the signal. To solve the error, the minimum value and the maximum value of the second derivative signal and the minimum value of the first derivative signal are used together to discriminate phases. For example, minimum and maximum peak values detected through the second derivative signal and minimum peak values detected through the first derivative signal are listed in chronological order, and thus, in a case, in which a minimum peak value of the second derivative signal, a minimum peak value of the first derivative signal, and a maximum peak value of the second derivative signal are sequentially detected, it is determined that a signal is a droplet signal.

An interface of a phase may be detected using the first derivative and the second derivative of the electrical signal of the optical fiber probe 10, and a parameter of an interface velocity may be measured based on the detected interface.

An interface velocity may be measured through a local phase velocity measurement method using an artificial intelligence learning method.

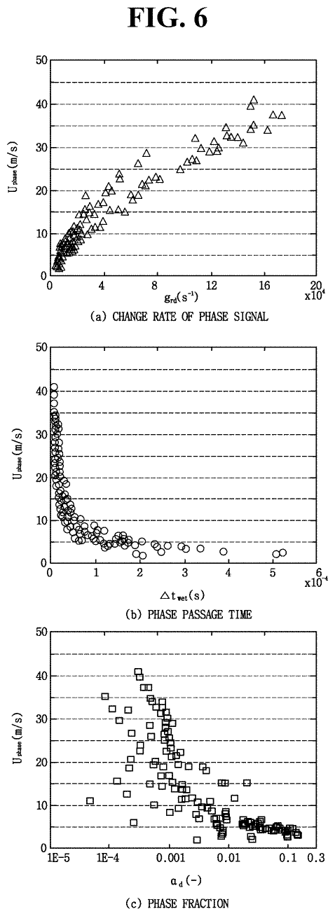

Three pieces of measurement data including a change rate g_{rd} of a signal generated when a phase (for example, a droplet) passes through a single optical fiber probe, an average time ΔT_{wet} taken for the phase to pass through the optical fiber probe, and a phase fraction α_{d} are used as input parameters of the artificial intelligence learning method of determining a phase velocity, and an interface velocity is obtained as an output parameter. FIG. 6 shows graphs showing relationships between a droplet or bubble and the three pieces of measurement data.

A procedure of the artificial intelligence learning method is as follows.

1) Experimental data on an input data set g_{rd}, ΔT_{wet}, and α_{d} and the output parameter, i.e., a droplet or bubble velocity are prepared for a calibration test.

2) A relationship between data randomly obtained from the input data and the corresponding droplet or bubble velocity is modeled using Bayesian normalization.

3) The learning model is evaluated using test data randomly extracted from the input data excluding the experimental data used for learning. A bias error calculated after the evaluation is defined by each test data item used as a weight of a subsequent operation.

4) The learning model is validated against experimental data excluding learning data used in a given time operation. The results of validation are quantified using an R-squared value. When the R-squared value does not satisfy an allowable criterion, the learning of operation 2 is repeated.

5) When the R-squared value satisfies a criterion, the learning is completed.

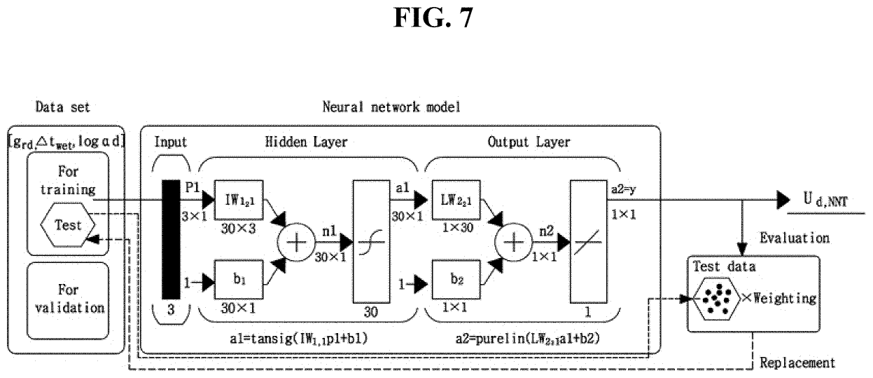

Thirty hidden neurons are provided in the artificial intelligence learning method, and a tangent sigmoid transfer function is used. A structure of a hidden layer is shown in FIG. 7

A convergence criterion of the artificial intelligence learning method is based on a mean square error, which is an average of squares of a deviation between a calculated value and a measured value of a velocity of a droplet or bubble.

Although the present invention has been described in detail above with reference to the embodiments, one of ordinary skill in the art to which the present invention pertains should be able to make various substitutions, additions, and modifications within the scope not departing from the above-described technical spirit, and such modified embodiments should also be understood as belonging to the scope of the present invention that is defined by the claims below.

Description of Reference Numerals

| | |
|---|---|
| 1: probe head | 2: first guide tube |
| 3: second guide tube | 4: probe holder |
| 10: optical fiber probe | 10a: core |
| 10b: cladding | 10c: coating material |
| 11: first tapered portion | 12: second tapered portion |

What is claimed is:

1. An optical fiber probe for measuring parameters of a local two-phase flow, which is fixed to a probe holder of a two-phase flow measuring device and is installed in a flow path of a two-phase flow of a liquid phase fluid and a gas phase fluid, the optical fiber probe comprising:
a first tapered portion which is formed in a conical shape in which a diameter is gradually decreased at a certain ratio in an axial direction thereof to a point spaced a certain distance from a point thereof fixed to a probe holder, toward a leading end of the optical fiber probe; and
a second tapered portion which is formed in a conical shape in which a diameter is gradually decreased at a greater ratio than that of the first tapered portion in an axial direction thereof from an end of the first tapered portion.

2. The optical fiber probe of claim 1, wherein an angle formed between an outer surface of the second tapered portion and a central axis thereof is 13.5°.

3. The optical fiber probe of claim 1, wherein a length of the first tapered portion is greater than a length of the second tapered portion.

4. The optical fiber probe of claim 1, wherein the first tapered portion and the second tapered portion are optical fibers made of a quartz material, and an outer surface of an optical fiber of the optical fiber probe excluding the first tapered portion and the second tapered portion is coated with a polymer or plated with a conductive metal according to a use temperature environment.

5. A method of manufacturing the optical fiber probe for measuring the parameters of the local two-phase flow of claim 1, the method comprising:
(S1) stretching one end of an optical fiber in an axial direction thereof to form a first tapered portion; and
(S2) immersing and etching an end of the first tapered portion in an etching solution to form a second tapered portion.

6. The method of claim 5, wherein the etching solution is a hydrofluoric acid solution.

7. A method of measuring parameters of a liquid phase fluid or a gas phase fluid of a local two-phase flow using the optical fiber probe for measuring the parameters of the local two-phase flow of claim 1, the method comprising:
(S11) acquiring a first derivative signal obtained by first-differentiating a raw signal detected by the optical fiber probe;
(S12) acquiring a second derivative signal by differentiating the first derivative signal; and
(S13) listing minimum and maximum peak values of the second derivative signal and minimum peak values of the first derivative signal in chronological order and determining a liquid phase fluid or a gas phase fluid.

8. The method of claim 7, wherein, in operation S13, a case, in which the minimum and maximum peak values detected through the second derivative signal and the minimum peak values detected through the first derivative signal are listed in chronological order to sequentially detect the minimum peak value of the second derivative signal, the minimum peak value of the first derivative signal, and the maximum peak value of the second derivative signal, is determined that a signal is a droplet signal.
